(19) United States
(12) Patent Application Publication
(10) Pub. No.: US 2019/0393289 A1
(43) Pub. Date: Dec. 26, 2019

(54) DISPLAY PANEL AND METHOD OF MANUFACTURING THEREOF

(71) Applicant: Wuhan China Star Optoelectronics Technology Co., Ltd., Wuhan, Hubei (CN)

(72) Inventor: Chongliang HU, Shenzhen, Guangdong (CN)

(21) Appl. No.: 15/748,803

(22) PCT Filed: Dec. 22, 2017
(86) PCT No.: PCT/CN2017/117972

§ 371 Date: Jan. 30, 2018

(30) Foreign Application Priority Data
Sep. 30, 2017 (CN) 2017109140612

(51) Int. Cl. H01L 27/32

(52) U.S. Cl. CPC H01L 27/3258; H01L 2227/323; H01L 27/3248; H01L 27/3246

(57) ABSTRACT

A method of manufacturing display panel and a display panel are provided. Preparing two electrodes on the active layer by deposition, photolithography, etching process. Depositing the second layer insulating layer on the first layer insulating layer. The second layer insulating layer is an organic layer could provide functions of buffer and adhesive the upper and bottom layers, and also enhances depth of the first contacting hole. The second layer insulating layer which corresponding to the forming first contacting hole region could remove by photolithography, etching process such that decreases the depth of the first contacting hole. Therefore, the source/drain formed by deposition could avoid easily broke problem caused overlong. It decreases the manufacturing difficult of forming source/drain while decreases depth of the first contacting hole.

### RELATED APPLICATIONS

The present application is a National Phase of International Application Number PCT/CN2017/117972, filed Dec. 22, 2017, and claims the priority of China Application No. 201710914061.2, filed Sep. 30, 2017.

### FIELD OF THE DISCLOSURE

The disclosure relates to a display technical field, and more particularly to a method of manufacturing display panel and a display panel.

### BACKGROUND

AMOLED is abbreviation of Active-matrix organic light emitting diode. According to the advantageous of the AMOLED such as fast response speed, highly contrast, wide view angle, the AMOLED is more and more applied to the device has display apparatus for example the portable terminal device (such as cell phone, tablet), television, vehicle terminal, personal computer and so on. Therefore, the AMOLED is called for next generation display technology.

Generally, method of manufacturing AMOLED display panel is forming a buffer layer, and then forming driving TFT and grid insulating layer, layer insulating layer on the buffer layer by deposition, photolithography, etching process. And sequentially forming the planar layer, anode, pixel defining layer and photoresist spacer on the layer insulating layer. This invention provides an improvement manufacturing method based on the existing technology, and enhances product yield.

### SUMMARY

A technical problem to be solved by the disclosure is to provide a method of manufacturing display panel and a display panel.

Furthermore, the disclosure further provides a method of manufacturing display panel, comprising

S1: providing a substrate, forming a buffer layer on the substrate by deposition;

S2: forming an active layer on the buffer layer;

S3: depositing a first grid insulating layer on the buffer layer, the first grid insulating layer is covering the active layer;

S4: depositing and patterning a first metal layer on the first grid insulating layer, and forming a first grid electrode, the first grid electrode is positioned above the active layer;

S5: depositing a second insulating layer on the first grid electrode, the second grid insulating layer is covering the first grid electrode;

S6: depositing and patterning a second metal layer on the second grid insulating layer, and forming a second grid electrode, the second grid electrode is positioned above the first grid electrode;

S7: depositing a first layer insulating layer on the second grid electrode, the first layer insulating layer is covering the second grid electrode;

S8: depositing a second layer insulating layer on the first layer insulating layer, and then etching the second layer insulating layer which correspondingly positioned above the active layer according to photolithography, etching process such that forming a blank region, only retaining the second layer insulating layer expect for the blank region;

S9: forming a first contacting hole on the first grid insulating layer, the second grid insulating layer and the first layer insulating layer which corresponding to two ends of the active layer;

forming source/drain on the black region of the first layer insulating layer, the source/drain are electrically connecting to the active layer by the first contacting hole;

S10: forming a planar layer on the first layer insulating layer and covering the source electrode/drain electrode and the second layer insulating layer; and forming a light-emitting functional layer on the planar layer.

In an embodiment, in the S2: forming an active layer on the buffer layer, which is depositing an amorphous silicon layer on the buffer layer, and treating the amorphous silicon layer by ELA (excimer laser annealing) for crystallization and transformation the amorphous silicon layer to a polycrystalline silicon, and patterning the polycrystalline silicon by photolithography, etching process for forming polycrystalline silicon regions, and then forming source/drain contacting regions are respectively on two ends of the polycrystalline silicon regions by deposition, photolithography, etching process.

In an embodiment, the light-emitting functional layer includes an anode, a second contacting hole, a pixel defining layer and a photoresist spacer and sequentially forming the planar layer, the anode is electrically connecting to the source/drain electrode by the second contacting hole.

In an embodiment, the second layer insulating layer is an organic layer, material of the organic layer is organic material or organogel.

In an embodiment, distance between the source/drain and the first grid electrode is 0.15-0.5 μm, the first grid electrode and the second grid electrode are parallel, and distance between the first grid electrode and the second grid electrode in vertical direction is 0.001-0.01 μm.

In an embodiment, thickness of the first grid insulating layer is 0.1-0.15 μm, thickness of the second grid insulating layer is 0.1-0.15 μm.

In an embodiment, thickness of the first grid insulating layer is 0.13 μm, thickness of the second grid insulating layer is 0.12 μm.

In an embodiment, thickness of the first layer insulating layer is 0.4-0.6 μm, thickness of the second layer insulating layer is 1.4-1.6 μm.

In an embodiment, thickness of the first layer insulating layer is 0.5 μm, thickness of the second layer insulating layer is 1.5 μm.

In an embodiment, materials of the first grid electrode and the second grid electrode is selective by one of consist of molybdenum, titanium, aluminum, copper or combination thereof.

In an embodiment, material of the buffer layer is silicon nitride, silicon dioxide or combination of both; material of the first layer insulating layer is silicon nitride, silicon dioxide or combination of both.

In an embodiment, material of the anode is indium tin oxide/silver/silver-SnO₂ composite.

According to another aspect of the disclosure, the disclosure further provides a display panel, comprising

a substrate;

a buffer layer is positioned on the substrate;

an active layer is positioned on the buffer layer;

a first grid insulating layer is positioned on the buffer layer and covering the active layer;

a first grid electrode is positioned on the first grid insulating layer, the first grid electrode is positioned above the active layer;

a second grid insulating layer is positioned on the first grid layer and covering the first grid electrode;

a second grid electrode is positioned on the second grid insulating layer, the second grid electrode is positioned above the first grid electrode;

a first layer insulating layer is positioned on the second grid insulating layer and covering the second grid electrode;

source electrode/drain are positioned on the first layer insulating layer;

a second layer insulating layer is positioned on a non-display region of the first layer insulating layer which is without overlapping with the active layer;

a planar layer is positioned on the first layer insulating layer and covering the source/drain and a second layer insulating layer; and

a light-emitting functional layer is positioned on the planar layer.

The active layer includes a polycrystalline silicon region and source/drain contacting regions are positioned on two ends of the polycrystalline silicon regions.

The display region is corresponding to a region removed the second layer insulating layer which above the active layer, and the region is corresponding to the blank region described above.

In an embodiment, the second layer insulating layer is an organic layer, material of the organic layer is organic material or organogel.

In an embodiment, distance between the source/drain and the first grid electrode is 0.15-0.5 μm, the first grid electrode and the second grid electrode are parallel, and distance between the first grid electrode and the second grid electrode in vertical direction is 0.001-0.01 μm.

In an embodiment, thickness of the first grid insulating layer is 0.1-0.15 μm, thickness of the second grid insulating layer is 0.1-0.15 μm.

In an embodiment, thickness of the first grid insulating layer is 0.13 μm, thickness of the second grid insulating layer is 0.12 μm.

In an embodiment, thickness of the first layer insulating layer is 0.4-0.6 μm, thickness of the second layer insulating layer is 1.4-1.6 μm.

In an embodiment, thickness of the first layer insulating layer is 0.5 μm, thickness of the second layer insulating layer is 1.5 μm.

In an embodiment, the light-emitting functional layer includes an anode, a second contacting hole, a pixel defining layer and photoresist spacer are positioned on the planar layer, the anode is electrically connecting to the source/drain by the second contacting hole.

In sum, the manufacturing method of display panel in step S8 which is that depositing a second layer insulating layer on the first layer insulating layer, the second layer insulating layer is an organic layer could provide functions of buffer and adhesive the upper and bottom layers. There have two grid electrodes of the display panel in this disclosure, which are the first grid electrode and the second grid electrode, respectively, and two of grid electrodes are respectively provides function of control different pixel switches. Even though the organic layer and two grid electrodes enhance toughness and display effect of display panel, but also increase depth of first contacting hole. Therefore, in the step S8 of this disclosure, removing the organic layer region (the second layer insulating layer) which is corresponding to the first contacting hole by photolithography, etching process such that decreases the depth of the first contacting hole. And then avoids the breaking issue about overlong of the source/drain which formed by deposition. Because the source/drain are made by metal and pass through the first grid insulating layer to the first layer insulating layer, which has a certain length and easily be broken, therefore decreases the depth of the first contacting hole is also decreases difficult of manufacturing the source/drain electrodes.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a cross sectional schematic view of a display panel manufactured by the method of this disclosure;

wherein 10 is substrate, 20 is buffer layer, 30 is first grid insulating layer, 40 is second grid insulating layer, 50 is first layer insulating layer, 60 is second layer insulating layer, 70 is planar layer. 80 is pixel defining layer, 90 is anode, 110 is photoresist spacer, 301 is source/drain contacting region, 302 is polycrystalline silicon regions, 304 is first contacting hole, 305 are source/drain electrodes, 41 is first grid electrode, 51 is second grid electrode, 91 is second contacting hole, 140 is blank region.

FIG. 2 is a schematic view of remove the second layer insulating layer which is correspondingly positioned above the active layer by photolithography, etching process;

FIG. 3 is a manufacturing flow chart diagraph of a display panel of this disclosure;

FIG. 4 is a sectional schematic view of the second layer insulating layer of the display panel which is correspondingly positioned above the active layer and without removing by photolithography, etching process;

FIG. 5 is a partial enlarged sectional view of a first contacting hole of the FIG. 4; and

FIG. 6 is a sectional schematic view of a first contacting hole is directly forming on the second layer insulating layer by photolithography, etching process.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

### Embodiment

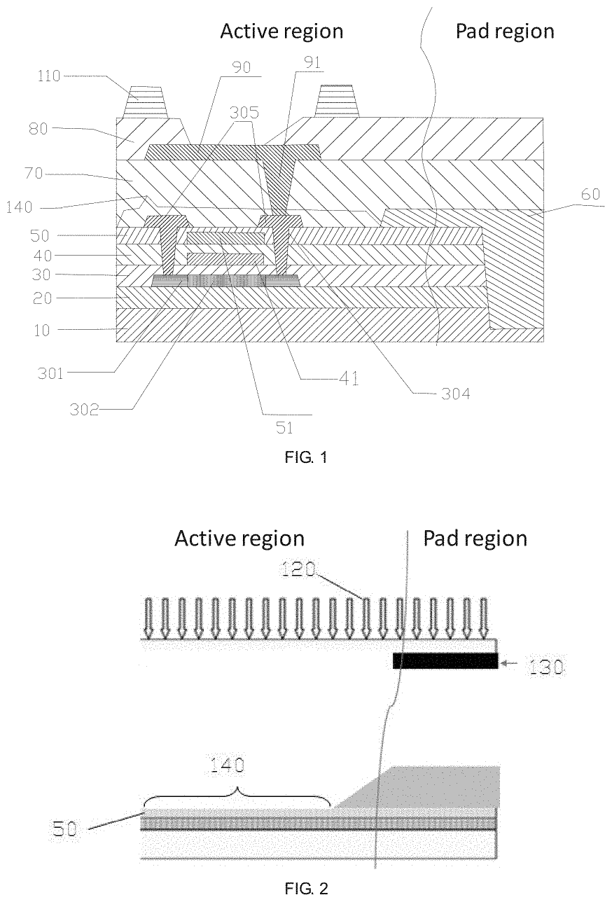

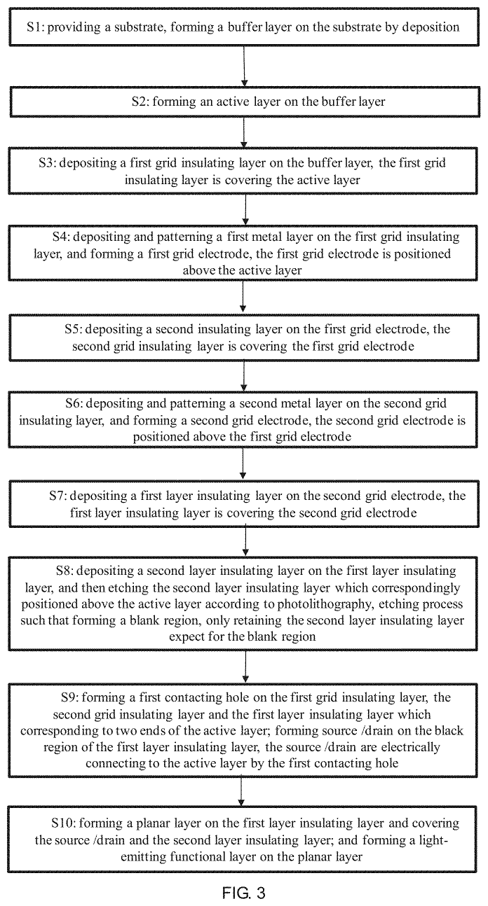

Please refer to FIG. 1 to FIG. 3. FIG. 1 is a schematic view of a display panel manufactured by the method of the first embodiment in this disclosure. FIG. 2 is a schematic view of remove the second layer insulating layer which is correspondingly positioned above the active layer by photolithography. FIG. 3 is a manufacturing flow chart diagraph of a display panel of the first embodiment in this disclosure. The manufacturing method of this disclosure comprises following steps.

S1: providing a substrate 10, forming a buffer layer 20 on the substrate 10 by deposition.

S2: forming an active layer (not shown) on the buffer layer 20. The active layer includes polycrystalline silicon regions 301 and source/drain contacting regions 302 are positioned on two ends of the polycrystalline silicon regions 301.

S3: depositing a first grid insulating layer 30 on the active layer. The first grid insulating layer 30 is covering the active layer which is formed on the buffer layer 20. The region of the first grid insulating layer 30 expect for the active layer is contacting to the buffer layer 20.

S4: depositing and forming the first metal layer (not shown) on the first grid insulating layer 30, and patterning the first metal layer to form a first grid electrode 41. The first grid electrode 41 is positioned above the active layer. The first grid electrode 41 is substantially parallel with the active layer, and has a certain distance in vertical direction.

S5: depositing the second insulating layer 40 on the first grid electrode 41, the second grid insulating layer 40 is covering the first grid electrode 41. The second grid insulating layer 40 is contacting to the first grid insulating layer expect for the region of covering the first grid electrode 41.

S6: depositing and forming the second metal layer on the second grid insulating layer 40, and patterning the second metal layer to form a second grid electrode 51. The second grid electrode is positioned above the first grid electrode, and has a certain distance with the first grid electrode in vertical direction.

S7: depositing a first layer insulating layer 50 on the second grid electrode 51, the first layer insulating layer 50 is covering the second grid electrode 51. The first grid insulating layer 50 is contacting to the second grid insulating layer expect for the region of covering the second grid electrode.

S8: depositing a second layer insulating layer 60 on the first layer insulating layer 50, and then etching the second layer insulating layer which is correspondingly positioned above the active layer according to photolithography, etching process such that forming a blank region 140, only retaining the second layer insulating layer 60 expect for the blank region 140.

S9: forming a first contacting hole 304 on the first grid insulating layer 30, the second grid insulating layer 40 and a first layer insulating layer 50 which corresponding to two ends of the active layer;

forming source/drain 305 on the black region 140 of the first layer insulating layer 50, the source/drain 305 are electrically connecting to the active layer by the first contacting hole 304. The source/drain 305 are electrically connecting with the source/drain contacting regions 302.

S10: forming a planar layer 70 on the first layer insulating layer 50 and covering the source/drain 305 and the second layer insulating layer 60; and forming a light-emitting functional layer (not shown) on the planar layer 70. The light-emitting functional layer includes an anode 90, a second contacting hole 91, a pixel defining layer 80 and photoresist spacer 110 and there are sequentially formed on the planar layer. The anode 90 is electrically connecting to the source/drain 305 by the second contacting hole 91.

Forming two grid electrodes by the previously step S4 and S6, which are the first grid electrode and the second grid electrode, respectively, and two of grid electrodes are respectively provides function of control different pixel switches.

In the further embodiment, the second layer insulating layer 60 is an organic layer, material of the organic layer is organic material or organogel. The second layer insulating layer 60 could provides functions of buffer and adhesive the upper and bottom layers.

In the above step S8, depositing a second layer insulating layer on the first layer insulating layer, the second layer insulating layer is an organic layer which could provides functions of buffer and adhesive the upper and bottom layers. Even though the organic layer and two grid electrodes enhance toughness and display effect of display panel, but also increase depth of first contacting hole. Therefore, in the step S8 removes the organic layer region which will forming the black region 140 that corresponding to the first contacting hole by photolithography, etching process such that decreases the depth of the first contacting hole, and then avoids the breaking issue about overlong of the source/drain which formed by deposition. Because the source/drain are made by metal and pass through the first grid insulating layer to the first layer insulating layer, which has a certain length and easily be broken, therefore decreases the depth of the first contacting hole is also decreases difficult of manufacturing the source/drain.

In the further embodiment, forming an active layer on the buffer layer 20 of S2, which is depositing an amorphous silicon layer on the buffer layer 20 and treating the amorphous silicon layer by ELA (excimer laser annealing) for crystallization and transformation the amorphous silicon layer to a polycrystalline silicon, and patterning the polycrystalline silicon by photolithography, etching process for forming polycrystalline silicon regions 302, and then forming source/drain contacting regions 302 are respectively positioned on two ends of the polycrystalline silicon regions 302 by deposition, photolithography, etching process.

The polycrystalline silicon regions 302, the source/drain contacting regions 301, the first grid electrode 41 and the second electrode 51 and the source/drain 305 composing to a driving TFT.

In the further embodiment, distance between the source/drain 305 and the first grid electrode 41 is 0.15-0.5 μm, the first grid electrode 41 and the second grid electrode 51 are parallel to each other. The distance between the first grid electrode 41 and the second grid electrode 51 in vertical direction is 0.001-0.01 μm.

In the further embodiment, thickness of the first grid insulating layer 30 is 0.1-0.15 μm, thickness of the second grid insulating layer 40 is 0.1-0.15 μm.

In the further embodiment, thickness of the first grid insulating layer 30 is 0.13 μm, thickness of the second grid insulating layer 40 is 0.12 μm.

In the further embodiment, thickness of the first layer insulating layer 50 is 0.4-0.6 μm, thickness of the second layer insulating layer 60 is 1.4-1.6 μm.

In the further embodiment, thickness of the first layer insulating layer 50 is 0.5 μm, thickness of the second layer insulating layer 60 is 1.5 μm.

In the further embodiment, materials of the first grid electrode 41 and the second grid electrode 51 are selective by one of consist of molybdenum, titanium, aluminum, copper or combination thereof.

In the further embodiment, material of the buffer layer 20 is silicon nitride, silicon dioxide or combination of both; material of the first layer insulating layer 50 is silicon nitride, silicon dioxide or combination of both.

In the further embodiment, material of the anode 80 is Indium tin oxide/silver/silver-SnO₂ composite.

Please refer to FIG. 1 again, a display panel provided by this disclosure. The display panel comprises a substrate 10; a buffer layer 20 is positioned on the substrate 10, and material of the buffer layer 20 is silicon nitride, silicon dioxide or combination of both. An active layer is positioned on the buffer layer 20. The active layer is not shown in the figure. The active layer includes polycrystalline silicon regions 302, a channel region and source/drain contacting regions 301, source/drain contacting regions 301 are positioned on two ends of the polycrystalline silicon regions 302.

A first grid insulating layer 30 is positioned on the buffer layer 20 and covering the active layer. The materials of the first grid electrode 30 is selective by one of the consist of molybdenum, titanium, aluminum, copper or combination thereof.

A first grid electrode 41 is positioned on the first grid insulating layer 30, the second insulating layer 40 is positioned on part of the first insulating layer 30 which covering the first grid electrode 41. The second insulating layer 40 is contacting with the first insulating layer 30 expect for the region of covering the first grid electrode 41. The materials of the second insulating layer 40 is selective by one of consist of molybdenum, titanium, aluminum, copper or combination thereof. The material of the second insulating layer 40 may or may not as same as the first insulating layer 30.

A second grid electrode 51 is positioned on the second grid insulating layer 40, the first layer insulating layer 50 is positioned on part of the second insulating layer 40 which covering the second grid electrode 51. The first layer insulating layer 50 is contacting with the second insulating layer 40 expect for the region of covering the second grid electrode 51. The material of the first layer insulating layer 50 is silicon nitride, silicon dioxide or combination of both.

The source/drain 305 are positioned on the first layer insulating layer 50. The first contacting hole 304 is positioned between the source/drain 305 and the source/drain contacting regions 301. The source/drain 305 are electrically connecting with the source/drain contacting regions 301 of the active layer by the first contacting hole 304. The source/drain 305 pass through the first layer insulating layer from the first grid insulating layer.

The polycrystalline silicon regions 302, the source/drain contacting regions 301, the first grid electrode 41 and the second electrode 51 and the source/drain 305 described above are composing to a driving TFT.

A second layer insulating layer 60 is positioned on a non-display region of the first layer insulating layer 50 which is without overlapping with the active layer in horizontal direction. That is positioned the second layer insulating layer 60 outside the black region 140 (display region). The second layer insulating layer 60 is an organic layer, material of the organic layer is organic material or organogel. It could provide functions of buffer and adhesive the upper and bottom layers.

A planar layer 70 is positioned on the first layer insulating layer 50 and covering the source/drain 305 and the second layer insulating layer 60, and a light-emitting functional layer is positioned on the planar layer 70 (not shown).

In the further embodiment, the light-emitting functional layer includes an anode 90, a second contacting hole 91, a pixel defining layer 80 and a photoresist spacer 110 are positioned on the planar layer 70, and the anode 90 is electrically connecting to the source/drain 305 by the second contacting hole 91. The material of the anode 80 is Indium tin oxide/silver/silver-SnO₂ composite. The material of the planar layer 70 is transparent resin.

In the further embodiment, distance between the source/drain 305 and the first grid electrode 41 is 0.15-0.5 μm, the first grid electrode 41 and the second grid electrode 51 are parallel to each other. The distance between the first grid electrode 41 and the second grid electrode 51 in vertical direction is 0.001-0.01 μm.

In the further embodiment, thickness of the first grid insulating layer 30 is 0.1-0.15 μm, thickness of the second grid insulating layer 40 is 0.1-0.15 μm.

In the further embodiment, thickness of the first grid insulating layer 30 is 0.13 μm, thickness of the second grid insulating layer 40 is 0.12 μm.

In the further embodiment, thickness of the first layer insulating layer 50 is 0.4-0.6 μm, thickness of the second layer insulating layer 60 is 1.4-1.6 μm.

In the further embodiment, thickness of the first layer insulating layer 50 is 0.5 μm, thickness of the second layer insulating layer 60 is 1.5 μm.

There have two grid electrodes setting in the TFT driving of display panel in this disclosure, which are the first grid electrode and the second grid electrode, respectively, and two of grid electrodes are respectively provides function of control different pixel switches.

The second layer insulating layer is positioned on the first layer insulating layer of the display panel in this disclosure, the second layer insulating layer is the organic layer could provide functions of buffer and adhesive the upper and bottom layers. Even though the organic layer and two grid electrodes enhance toughness and display effect of display panel, but also increase depth of first contacting hole. Therefore, removing the organic layer region which is corresponding to the first contacting hole according to photolithography, etching process such that decreases the depth of the first contacting hole. And then avoids the breaking issue about overlong of the source/drain which formed by deposition, also decreases difficult of manufacturing the source/drain, enhances yield of the display panel.

### Comparative Embodiment

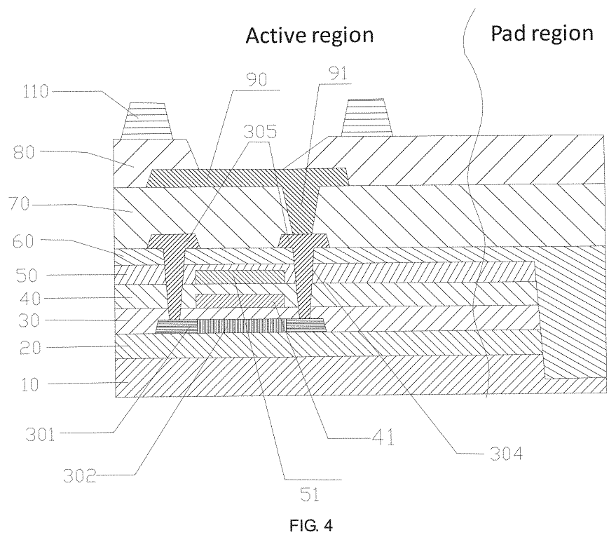

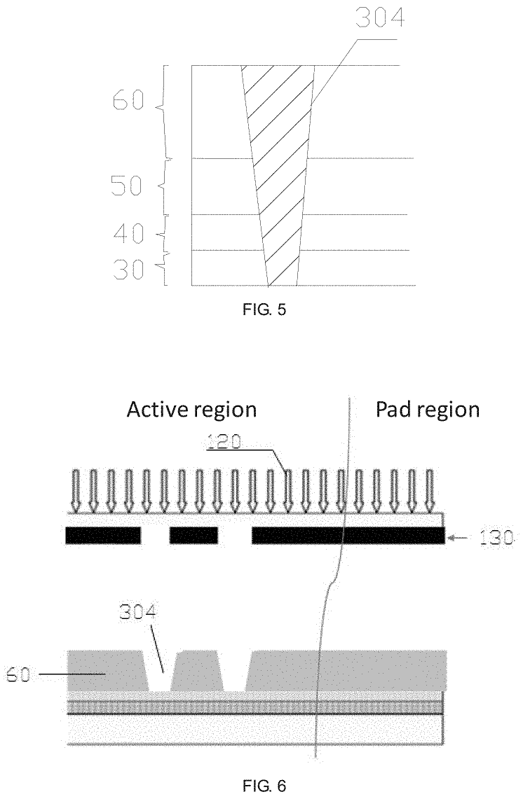

In order to convenience understand this disclosure, in this embodiment further provides a comparative embodiment for describes invention idea and invention. As shown in FIG. 4. FIG. 4 is a sectional schematic view of the second layer insulating layer of the display panel which is correspondingly positioned above the active layer and without removing by photolithography, etching process. It shows that the depth of the first contacting hole in FIG. 4 is deeper than the depth of the first contacting hole in FIG. 1. Combine with the FIG. 5. FIG. 5 is a partial enlarged sectional view of a first contacting hole shows in FIG. 1 of the display panel. The thickness of the second layer insulating layer 60 is 1.5 μm, thickness of the first layer insulating layer 50 is 0.5 μm, thickness of the second grid insulating layer 40 is 0.12 μm, thickness of the first grid insulating layer 30 is 0.13 μm.

If using the photolithography, etching process in the FIG. 6, as shown in FIG. 6, positioning the mask membrane 130 above the second layer insulating layer 60, patterning to form the first contacting hole 304, and forming the first contacting hole 304 on the second layer insulating layer by etching process after lighting 120. At this time, depth of the first contacting hole 304 is totally thickness of the second layer insulating layer 60, the first layer insulating layer 50, the second grid insulating layer 40 and the first grid insulating layer, which is 2.3 μm.

However, if using the photolithography, etching process of this embodiment in this disclosure, as FIG. 2. Removing region of the second layer insulating layer 60 which is correspondingly positioned above active layer, which is the blank region 140, by photolithography, etching process. At this time, depth of the first contacting hole is totally thickness of the first layer insulating layer 50, the second grid insulating layer 40, the first grid insulating layer 30, is 0.6 μm. It reduces 1.5 μm depth of the first contacting hole comparing to the method of FIG. 6, which is about 65%. Therefore, it greatly decreases difficult of manufacturing method and decreases depth of the first contacting hole 34 such that it is not easily broken while forming the source/drain during depositing metal film. It enhances yield of display panel.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A method of manufacturing display panel, comprising
S1: providing a substrate, forming a buffer layer on the substrate by deposition;
S2: forming an active layer on the buffer layer;
S3: depositing a first grid insulating layer on the buffer layer, the first grid insulating layer is covering the active layer;
S4: depositing and patterning a first metal layer on the first grid insulating layer, and forming a first grid electrode, the first grid electrode is positioned above the active layer;
S5: depositing a second insulating layer on the first grid electrode, the second grid insulating layer is covering the first grid electrode;
S6: depositing and patterning a second metal layer on the second grid insulating layer, and forming a second grid electrode, the second grid electrode is positioned above the first grid electrode;
S7: depositing a first layer insulating layer on the second grid electrode, the first layer insulating layer is covering the second grid electrode;
S8: depositing a second layer insulating layer on the first layer insulating layer, and then etching the second layer insulating layer which correspondingly positioned above the active layer according to photolithography, etching process such that forming a blank region, only retaining the second layer insulating layer expect for the blank region;
S9: forming a first contacting hole on the first grid insulating layer, the second grid insulating layer and the first layer insulating layer which corresponding to two ends of the active layer;
forming source/drain on the black region of the first layer insulating layer, the source/drain are electrically connecting to the active layer by the first contacting hole;
S10: forming a planar layer on the first layer insulating layer and covering the source/drain and the second layer insulating layer; and forming a light-emitting functional layer on the planar layer.

2. The method of manufacturing display panel according to claim 1, wherein in the S2: forming an active layer on the buffer layer, which is depositing an amorphous silicon layer on the buffer layer, and treating the amorphous silicon layer by ELA (excimer laser annealing) for crystallization and transformation the amorphous silicon layer to a polycrystalline silicon, and patterning the polycrystalline silicon by photolithography, etching process for forming polycrystalline silicon regions, and then forming source/drain contacting regions are respectively on two ends of the polycrystalline silicon regions by deposition, photolithography, etching process.

3. The method of manufacturing display panel according to claim 1, wherein the second layer insulating layer is an organic layer, material of the organic layer is organic material or organogel.

4. The method of manufacturing display panel according to claim 1, wherein materials of the first grid electrode and the second grid electrode is selective by one of consist of molybdenum, titanium, aluminum, copper or combination thereof.

5. A display panel, comprising
a substrate;
a buffer layer positioned on the substrate;
an active layer positioned on the buffer layer;
a first grid insulating layer positioned on the buffer layer and covering the active layer;
a first grid electrode positioned on the first grid insulating layer, the first grid electrode positioned above the active layer;
a second grid insulating layer positioned on the first grid layer and covering the first grid electrode;
a second grid electrode positioned on the second grid insulating layer, the second grid electrode is positioned above the first grid electrode;
a first layer insulating layer positioned on the second grid insulating layer and covering the second grid electrode;
source electrode/drain positioned on the first layer insulating layer;
a second layer insulating layer positioned on a non-display region of the first layer insulating layer which is without overlapping with the active layer;
a planar layer positioned on the first layer insulating layer and covering the source/drain and a second layer insulating layer; and
a light-emitting functional layer positioned on the planar layer.

6. The display panel according to claim 5, wherein the second layer insulating layer is an organic layer, and material of the organic layer is organic material or organogel.

7. The display panel according to claim 5, wherein distance between the source/drain and the first grid electrode is 0.15-0.5 μm, the first grid electrode and the second grid electrode are parallel, and distance between the first grid electrode and the second grid electrode in vertical direction is 0.001-0.01 μm.

8. The display panel according to claim 5, wherein thickness of the first grid insulating layer is 0.1-0.15 μm, thickness of the second grid insulating layer is 0.1-0.15 μm.

9. The display panel according to claim 5, wherein thickness of the first layer insulating layer is 0.4-0.6 μm, thickness of the second layer insulating layer is 1.4-1.6 μm.

10. The display panel according to claim 5, wherein the light-emitting functional layer is an anode, a second contacting hole, a pixel defining layer and a photoresist spacer, the anode is electrically connecting to the source/drain by the second contacting hole.
